(19) United States
(12) Patent Application Publication
(10) Pub. No.: US 2026/0354291 A1
(43) Pub. Date: Nov. 5, 2026

(54) POLYSiC WAFER BASE WITH MANDREL DEFINED POWER AND GROUND RAILS

(71) Applicant: Microchip Technology Inc., Chandler, AZ (US)

(72) Inventors: Steve Nagel, Chandler, AZ (US); Bomy Chen, Newark, CA (US)

(73) Assignee: Microchip Technology Inc., Chandler, AZ (US)

(21) Appl. No.: 19/269,151

(22) Filed: Jul. 15, 2025

Related U.S. Application Data
(60) Provisional application No. 63/798,797, filed on May 2, 2025.

(51) Int. Cl. H10W 99/00; H10W 70/05; H10W 70/692

(52) U.S. Cl. CPC H10W 99/00; H10W 70/05; H10W 70/692

(57) ABSTRACT

A method provides a silicon wafer shaped to have a silicon base at the backside and a silicon mandrel at the frontside, forming a ceramic wafer with silicon mandrel, removing the silicon mandrel from the ceramic wafer to form a feature in a frontside of the ceramic wafer, and inputting a conductive material in the feature to form a backside power line. A system has a ceramic wafer of SiC powder heated and pressed into an amorphous poly-SiC ceramic, a power line and a power rail in the backside of the ceramic wafer, and a semiconductor package applied to the frontside of the ceramic wafer.

### CROSS-REFERENCE TO RELATED APPLICATIONS

This application claims priority to U.S. Provisional Patent Application No. 63/798,797, filed May 2, 2025, which is hereby incorporated by reference in its entirety for all purposes as if fully set forth herein.

### TECHNICAL FIELD

The present disclosure relates to interposers, in particular, amorphous polySiC ceramic wafers with power and ground rails.

### BACKGROUND

Silicon wafers have a frontside and a backside. The frontside refers to the polished surface where integrated circuits (ICs) and other device structures are built. The backside of a silicon wafer is the opposite surface of the frontside and may or may not be polished and can be used for various purposes, including power delivery, inspection, and dicing.

Traditionally, power and signal interconnects are both placed on the frontside of the silicon wafer. Backside power delivery (BPD) separates these functions by placing power delivery interconnects on the backside of the wafer, thereby freeing up more space for signal interconnects on the frontside. BPD has been done utilizing silicon. Some designs demonstrate backside power delivery using silicon with standard patterning techniques and processes.

Smaller semiconductor devices present power delivery issues: electrical isolation, limitations on feature sizes, losses due to traversing large numbers of metal layers, and so forth. BPD may address these issues by separating power delivery from signal routing. BPD decouples power and signal interconnects on a chip freeing up space for signal connections on the frontside, improving performance, efficiency and transistor density. Forming packaged semiconductor devices having IC dies, which include backside power rails, may allow for the IC dies to be formed with greater transistor densities, reduces distances between bonded IC dies, and may provide for greater flexibility in IC die stacking and packaging. However, BPD may complicate manufacturing processes.

There is a need for ceramic wafers with efficient power delivery.

### SUMMARY

According to aspects, there is provided a method comprising: providing a silicon wafer having a frontside to have integrated circuits built thereon and a backside; shaping the silicon wafer to have a silicon base at the backside and a silicon mandrel having a proximal end at the silicon base and a distal end at the frontside; forming a ceramic wafer comprising the silicon mandrel; removing the silicon mandrel from the ceramic wafer to form a feature in a frontside of the ceramic wafer; and inputting a conductive material comprising tungsten in the feature to form a power line.

Aspects as in the preceding paragraph provides a method, wherein shaping the silicon wafer comprises: applying a photoresist pattern to the frontside of the silicon wafer; and etching the silicon wafer through the photoresist pattern to remove exposed portions of the silicon wafer and form the silicon mandrel.

Aspects as in one of the preceding two paragraphs provides a method, wherein forming a ceramic wafer comprises: covering the frontside of the silicon wafer having the silicon mandrel with a SiC powder; and heating and pressing the SiC powder into an amorphous polySiC ceramic.

Aspects as in one of the preceding three paragraphs provides a method, wherein removing the silicon mandrel from the ceramic wafer comprises washing the backside of the ceramic wafer with a fluid to dissolve the silicon base and the silicon mandrel.

Aspects as in one of the preceding four paragraphs provides a method, wherein inputting a conductive material comprising tungsten in the feature is to form a power rail.

Aspects as in one of the preceding five paragraphs provides a method, comprising: applying a spin on glass layer to the frontside of the ceramic wafer.

Aspects as in one of the preceding six paragraphs provides a method, wherein the spin on glass layer comprises particles having a relatively higher heat transfer coefficient than a material of the spin on glass layer.

Aspects as in one of the preceding seven paragraphs provides a method, comprising applying a silicon photonics package to the ceramic wafer.

Aspects as in one of the preceding eight paragraphs provides a method, comprising applying a CMOS package to the ceramic wafer.

Aspects as in one of the preceding nine paragraphs provides a method, comprising applying a vertical III-V device to the ceramic wafer.

According to aspects, there is provided a device comprising: a ceramic wafer having a frontside to have integrated circuits built thereon and a backside, wherein the ceramic wafer comprises a SiC powder heated and pressed into an amorphous poly-SiC ceramic; and a power line in the ceramic wafer, the power line comprising a conductive material comprising tungsten.

Aspects as in the preceding paragraph provides a device, wherein a thickness of the ceramic wafer is between 100-600 μm.

Aspects as in one of the preceding two paragraphs provides a device, comprising a power rail in the ceramic wafer, the power rail comprising a conductive material comprising tungsten, wherein the power rail is in electrical communication with the power line.

Aspects as in one of the preceding three paragraphs provides a device, comprising a spin on glass layer on the frontside of the ceramic wafer.

Aspects as in one of the preceding four paragraphs provides a device, wherein the spin on glass layer comprises particles having a relatively higher heat transfer coefficient than a material of the spin on glass layer.

Aspects as in one of the preceding five paragraphs provides a device, wherein a thickness of the spin on glass layer is between 2 and 20 μm, and the particles have a diameter dimension between .1 and 10 μm.

According to aspects, there is provided a system comprising: a ceramic wafer having a frontside and a backside, wherein the ceramic wafer comprises a SiC powder heated and pressed into an amorphous poly-SiC ceramic; a power line comprising a conductive material comprising tungsten in the ceramic wafer; a power rail comprising a conductive material comprising tungsten in the ceramic wafer, wherein the power rail is in electrical communication with the power line; and a semiconductor package applied to the ceramic wafer.

Aspects as in the preceding paragraph provides a system, wherein the semiconductor package comprises silicon photonics.

Aspects as in one of the preceding two paragraphs provides a system, wherein the semiconductor package comprises a CMOS device.

Aspects as in one of the preceding three paragraphs provides a system, wherein the semiconductor package comprises a vertical III-V device.

### BRIEF DESCRIPTION OF THE DRAWINGS

A more complete understanding of the disclosure and the advantages thereof may be acquired by referring to the following description, taken in conjunction with the accompanying drawings and wherein:

FIG. 1A shows a cross-sectional side view of a silicon wafer 102 before power mandrels are therein formed.

FIG. 1B shows a cross-sectional side view of the silicon wafer of FIG. 1A, wherein first patterned photoresist is applied to the silicon wafer.

FIG. 1C shows a cross-sectional side view of the silicon wafer of FIG. 1B, wherein the silicon wafer is etched through the first patterned photoresist to produce silicon mandrels.

FIG. 1D shows a cross-sectional side view of the silicon mandrels of FIG. 1C, wherein the first patterned photoresist is removed from the silicon mandrels.

FIG. 1E shows a cross-sectional side view of the silicon mandrels of FIG. 1D, wherein the silicon mandrels and the remaining silicon wafer are covered with a SiC powder and hot pressed to form an amorphous polySiC ceramic.

FIG. 1F shows a cross-sectional side view of the ceramic wafer of FIG. 1E, wherein the ceramic wafer 114 is flipped up-side-down.

FIG. 1G shows a cross-sectional side view of the ceramic wafer of FIG. 1F, wherein the openings in the ceramic wafer are filled with tungsten.

FIG. 1H shows a cross-sectional side view of the ceramic wafer of FIG. 1F, wherein some of the openings in the ceramic wafer are filled with tungsten.

FIG. 1I shows a cross-sectional side view of the ceramic wafer of FIG. 1G, wherein the tungsten and the ceramic wafer are chemical mechanical polished (CMP) on both sides.

FIG. 1J shows a perspective front-top view of the ceramic wafer of FIG. 1I.

FIG. 1K shows a bottom view of the ceramic wafer 114 of FIG. 1I.

FIG. 1L shows a perspective front-top view of the ceramic wafer of FIGS. 1J and 1K, wherein a spin on glass (SOG) layer is applied to the frontside.

FIG. 2 shows a cross-sectional side view of a ceramic wafer being used in a silicon photonics package.

FIG. 3A shows a perspective front-top view of two ceramic wafers of FIG. 1L for use in a CMOS package.

FIG. 3B shows a cross-sectional side view of a CMOS package using the ceramic wafers of FIG. 3A.

FIG. 4A shows a perspective front-top view of a ceramic wafer of FIG. 1L for use in a vertical III-V device.

FIG. 4B shows a transistor for use in the vertical III-V device of FIG. 4A.

The drawings accompanying and forming part of this specification are included to depict certain aspects of the disclosure. The reference number for any illustrated element that appears in multiple different figures has the same meaning across the multiple figures, and the mention or discussion herein of any illustrated element in the context of any particular figure also applies to each other figure, if any, in which that same illustrated element is shown. The features illustrated in the drawings are not necessarily drawn to scale. It should be noted that the features illustrated in the drawings are not necessarily drawn to scale.

### DESCRIPTION

According to aspects, there is provided a process of creating a ceramic wafer with backside power delivery. Aspects of the process make a ceramic wafer using a pressed ceramic verses starting with a single crystal substrate. A silicon wafer has applied thereto a diamondized (with heat transfer nano-particles) spin on glass (SoG) layer for improved heat transfer. A silicon mandrel is provided and a process is used to press SiC power to form the location of power lines. Aspects of the process use pressed poly-SiC (powder) to form the wafer. The wafer is processed and then the mandrel is removed to expose openings in the wafer. Tungsten is then deposited or select deposited in the openings in the wafer to form power lines. This process may provide a less expensive wafer substrate with backside power lines that has good heat transfer characteristics.

Aspects provide a process for adding buried tungsten power and ground lines to a ceramic wafer. Aspects provide for separate power lines in the backside of a silicon wafer and signal lines in the frontside of the silicon wafer. Aspects may integrate vertical field-effect transistors (FETs) with planar or FINFET transistors to dissipate heat of SiC at lower production cost.

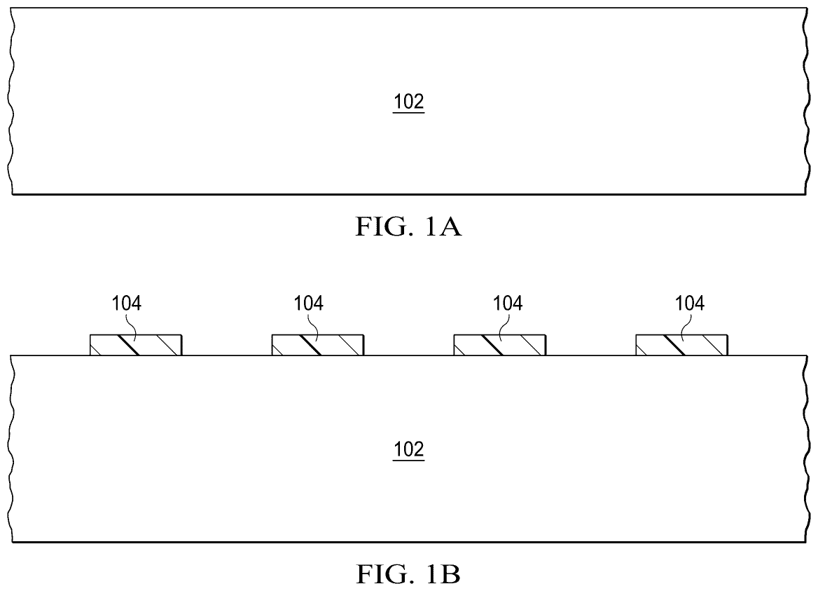

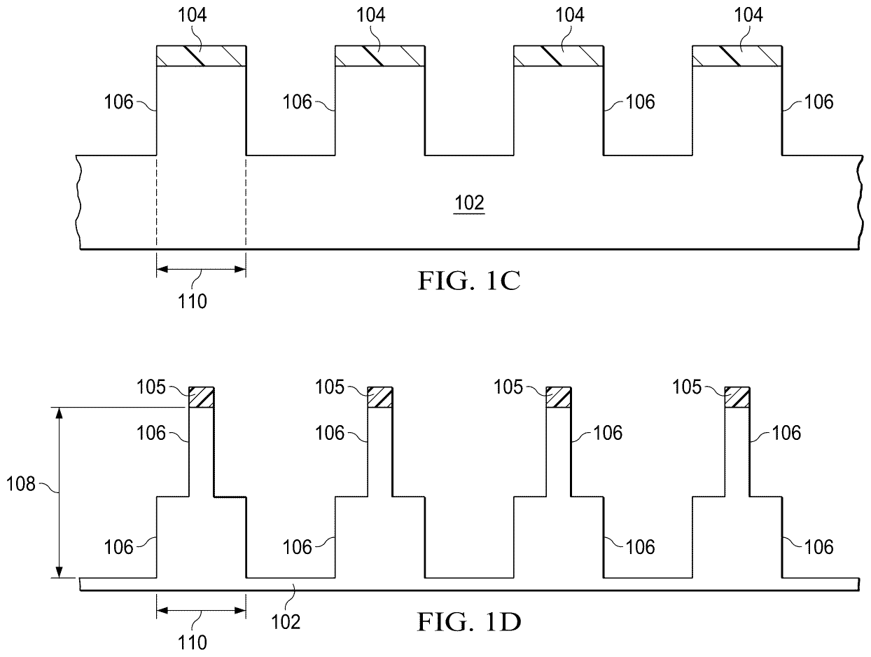

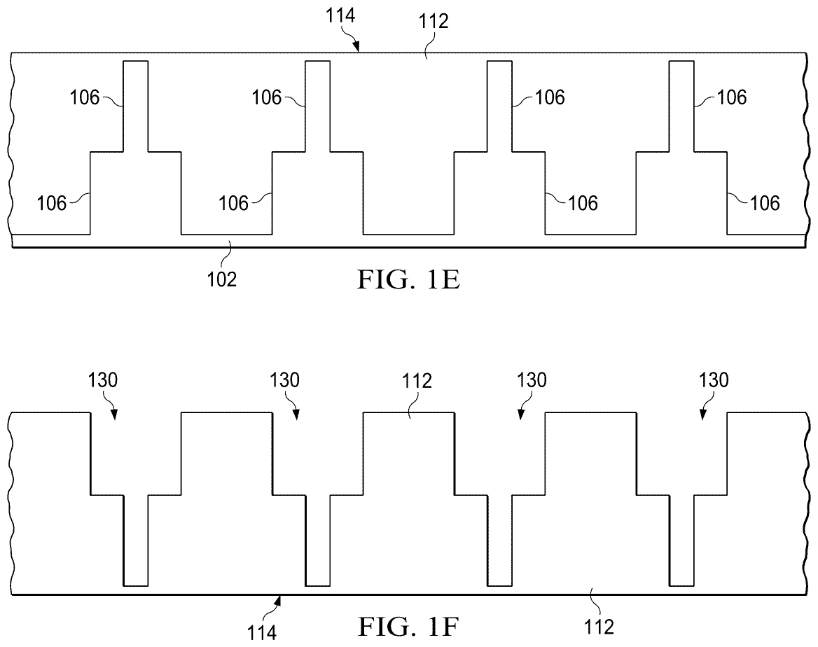

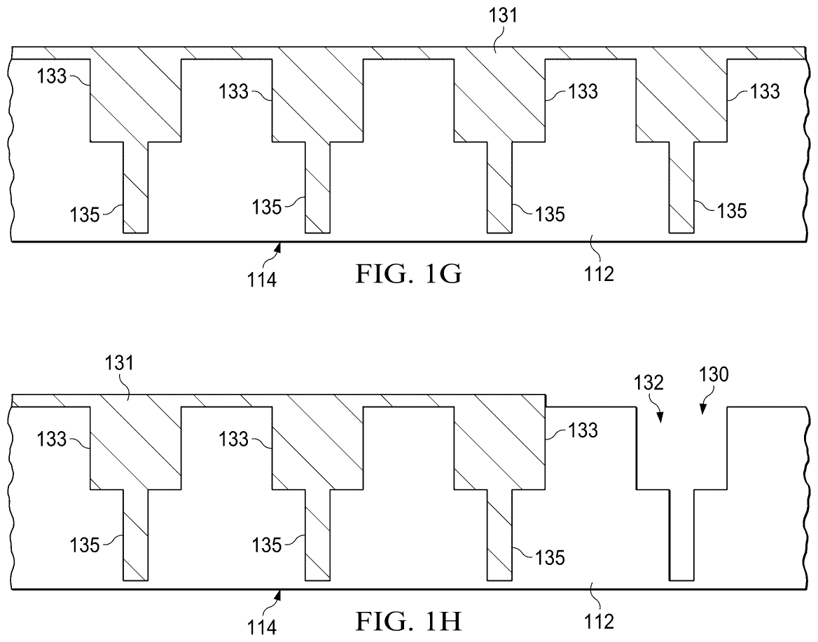

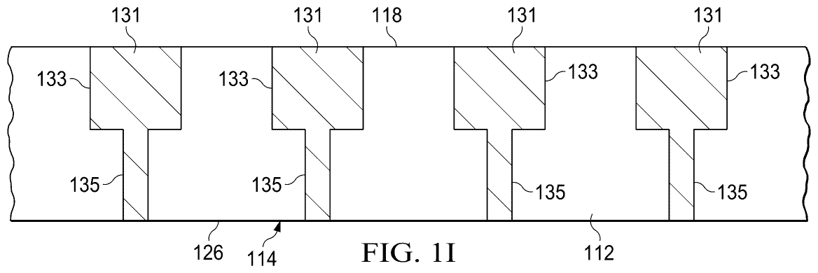

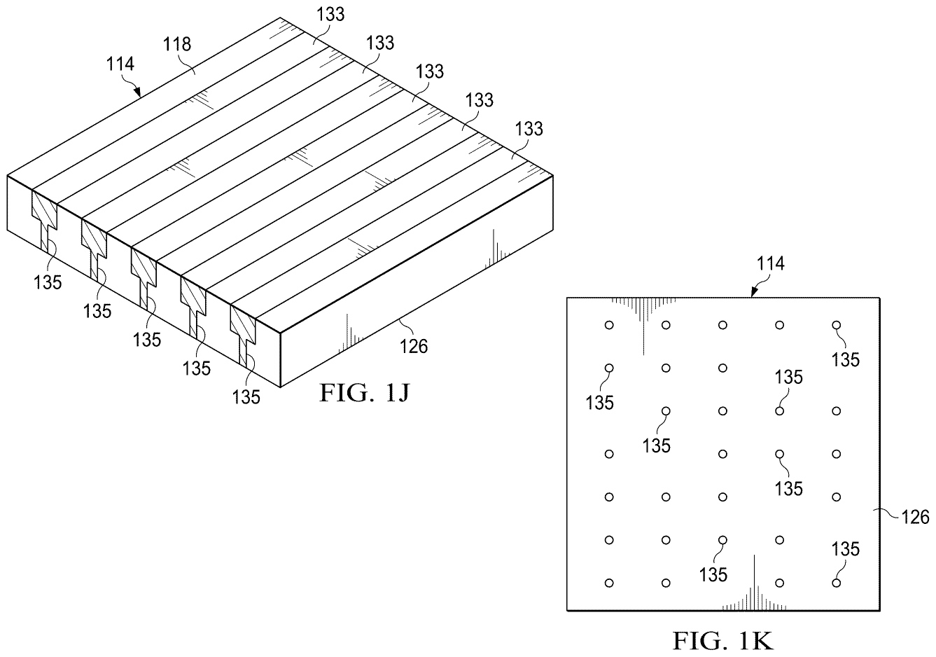

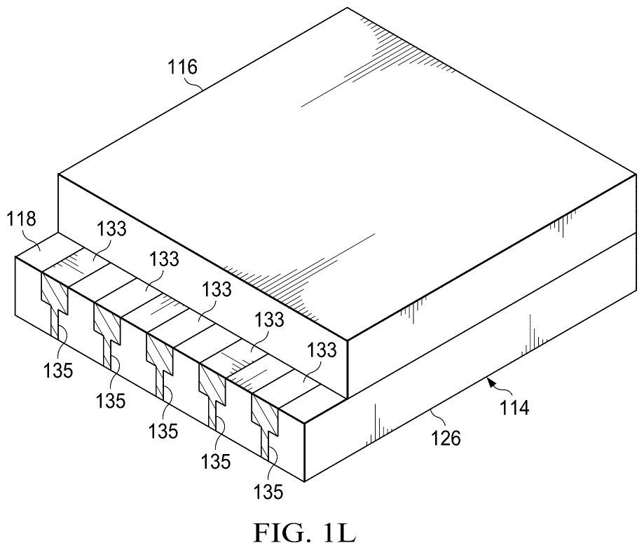

FIG. 1A-1L show cross-sectional side views of a pressed ceramic wafer having power lines at various fabrication developments.

FIG. 1A shows a cross-sectional side view of a silicon wafer 102 before power mandrels are therein formed.

FIG. 1B shows a cross-sectional side view of the silicon wafer 102 of FIG. 1A. A first patterned photoresist 104 is applied to the silicon wafer 102. The first patterned photoresist 104 may be lines of photoresist to etch grooves or channels between the lines.

FIG. 1C shows a cross-sectional side view of the silicon wafer 102 of FIG. 1B. The silicon wafer 102 is etched through the first patterned photoresist 104 to produce silicon mandrels 106. The etch process may be a reactive-ion etch process. Alternatively, the silicon mandrels 106 may comprise tall silicon dots stacked to form a column or mandrel. Thin Si₃N₄ separation with may be obtained with polycrystalline silicon carbide (pSiC).

FIG. 1D shows a cross-sectional side view of the silicon mandrels 106 of FIG. 1C. The first patterned photoresist 104 (see FIG. 1C) is removed from the silicon mandrels 106. A second patterned photoresist 105 is applied to the silicon wafer 102, wherein this pattern is an array of dots or circular patches of photoresist. The diameters of the circular patches of the second patterned photoresist 105 are smaller than the width of the lines of the first patterned photoresist 104 (see FIG. 1C). The etch process may be a reactive-ion etch process. The silicon mandrels 106 may have a height 108 of 100-600 μm and a width 110 of 50-500 μm. A thin silicon nitride film (not shown) may then optionally be deposited.

FIG. 1E shows a cross-sectional side view of the silicon mandrels 106 of FIG. 1D. The silicon mandrels 106 and the remaining silicon wafer 102 are covered with a SiC powder and hot pressed to form an amorphous polySiC ceramic 112. Thus, a ceramic wafer 114 using a pressed ceramic is created with silicon mandrels 106.

FIG. 1F shows a cross-sectional side view of the ceramic wafer 114 of FIG. 1E, wherein the ceramic wafer 114 is flipped up-side-down. The silicon mandrels 106 and silicon wafer 102 (see FIG. 1E) may be removed from the ceramic wafer 114 by a potassium hydroxide (KOH) wash, to produce via openings 130 in the ceramic wafer 114.

FIG. 1G shows a cross-sectional side view of the ceramic wafer 114 of FIG. 1F, wherein the openings 130 (see FIG. 1E) in the ceramic wafer 114 are filled with tungsten 131 by blanket deposition or select deposition. The ceramic wafer 114 now has lines 133 and vias 135 therein.

FIG. 1H shows a cross-sectional side view of the ceramic wafer 114 of FIG. 1F, wherein some of the openings 130 (see FIG. 1E) in the ceramic wafer 114 are filled with tungsten 131 by blanket deposition or select deposition to form lines 133 and vias 135 therein. Openings 130 may be left open to form air gaps, channels, or other features 132 in the ceramic wafer 114.

FIG. 1I shows a cross-sectional side view of the ceramic wafer 114 of FIG. 1G, wherein the tungsten 131 and the ceramic wafer 114 are chemical mechanical polished (CMP) on both sides to remove excess tungsten and amorphous polySiC ceramic. The lines 133 and vias 135 extend through the ceramic wafer 114 from a frontside 118 to a backside 126 to provide conductive pathways therethrough.

FIG. 1J shows a perspective front-top view of the ceramic wafer 114 of FIG. 1I. FIG. 1K shows a bottom view of the ceramic wafer 114 of FIG. 1I. The lines 133 extend through the frontside 118 and the vias 135 extend through the backside 126 of the ceramic wafer 114.

FIG. 1L shows a perspective front-top view of the ceramic wafer 114 of FIGS. 1J and 1K. A spin on glass (SOG) layer 116 is applied to the frontside 118 of the ceramic wafer 114 and annealed. The spin on glass (SOG) layer 116 may contain heat transfer enhancing particles, like diamond, AlN, or SiC, and may further provide a layer to reduce or prohibit eddy currents from being transferred through the ceramic wafer 114.

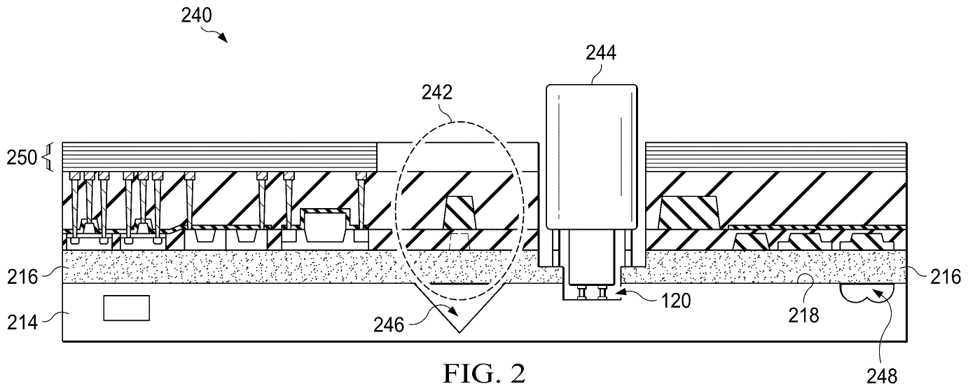

FIG. 2 shows a cross-sectional side view of a ceramic wafer 214 being used in a silicon photonics package 240. A spin on glass (SOG) layer 216 is applied to the ceramic wafer 214. The ceramic wafer 214 has a channel feature 246 for receiving a single-mode fiber cable 142. The silicon photonics package 240 has various integrated circuits (ICs) and other device structures built on the frontside 218 of the ceramic wafer 214, including: nFETs, SiGe pFET, modulators, detectors, SiWG, without limitation. The silicon photonics package 240 has a laser 244 that sends light signals via the single-mode fiber cable 242. Back end of line (BEOL) metal interconnect layers 250 are applied over the integrated circuits of the silicon photonics package 240.

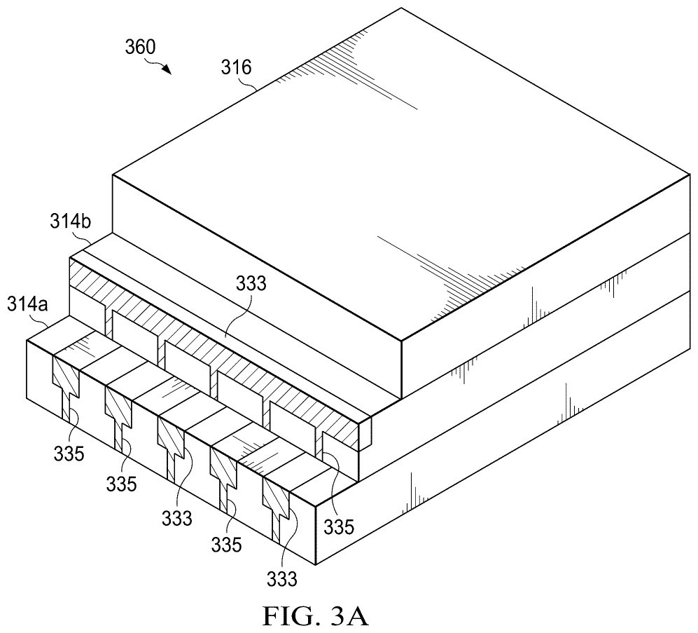

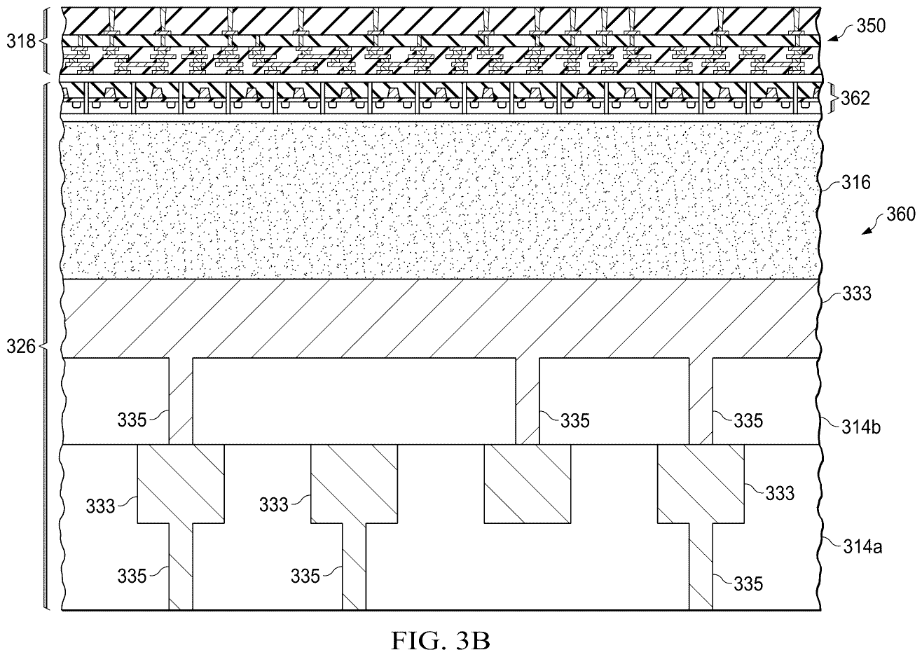

FIG. 3A shows a perspective front-top view of two ceramic wafers of FIG. 1L for use in a CMOS package 360. FIG. 3B shows a cross-sectional side view of a CMOS package 360 using the ceramic wafers of FIG. 3A. Any number of ceramic wafers may be stacked to route backside conductive pathways according to design parameters. In FIGS. 3A and 3B, two ceramic wafers 314a and 314b are stacked to form the backside 326 to provide lines 333 and vias 335 for backside power delivery. The CMOS package 360 has a SOG layer 316, which may contain heat transfer enhancing particles, like diamond, AlN, or SiC, and may further provide a layer to reduce or prohibit eddy currents from being transferred through the ceramic wafers 314a and 314b. On the frontside 318, transistors 362 are built on the SOG layer 316 and back end of line (BEOL) metal interconnect layers 350 are applied over the transistors 362.

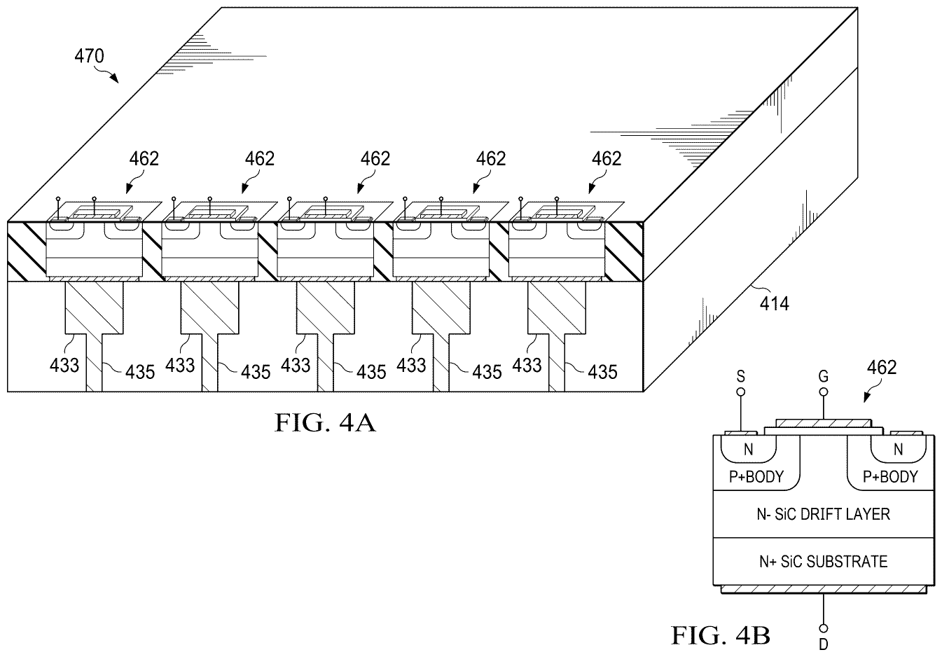

FIG. 4A shows a perspective front-top view of a ceramic wafer of FIG. 1L for use in a vertical III-V device 470. FIG. 4B shows a transistor 462 for use in the vertical III-V device 470 of FIG. 4A, to turn OFF/ON power at an individual via 435 or line 433. A ceramic wafer 414 may be used in both SiC and vGaN vertical III-V devices.

Although examples have been described above, other variations and examples may be made from this disclosure without departing from the spirit and scope of these disclosed examples.

What is claimed is:

1. A method comprising:
providing a silicon wafer having a frontside to have integrated circuits built thereon and a backside;
shaping the silicon wafer to have a silicon base at the backside and a silicon mandrel having a proximal end at the silicon base and a distal end at the frontside;
forming a ceramic wafer comprising the silicon mandrel;
removing the silicon mandrel from the ceramic wafer to form a feature in a frontside of the ceramic wafer; and
inputting a conductive material comprising tungsten in the feature to form a power line.

2. The method as in claim 1, wherein shaping the silicon wafer comprises:
applying a photoresist pattern to the frontside of the silicon wafer; and
etching the silicon wafer through the photoresist pattern to remove exposed portions of the silicon wafer and form the silicon mandrel.

3. The method as in claim 1, wherein forming a ceramic wafer comprises:
covering the frontside of the silicon wafer having the silicon mandrel with a SiC powder; and
heating and pressing the SiC powder into an amorphous polySiC ceramic.

4. The method as in claim 1, wherein removing the silicon mandrel from the ceramic wafer comprises washing the backside of the ceramic wafer with a fluid to dissolve the silicon base and the silicon mandrel.

5. The method as in claim 1, wherein inputting a conductive material comprising tungsten in the feature is to form a power rail.

6. The method as in claim 1, comprising:
applying a spin on glass layer to the frontside of the ceramic wafer.

7. The method as in claim 6, wherein the spin on glass layer comprises particles having a relatively higher heat transfer coefficient than a material of the spin on glass layer.

8. The method as in claim 1, comprising applying a silicon photonics package to the ceramic wafer.

9. The method as in claim 1, comprising applying a CMOS package to the ceramic wafer.

10. The method as in claim 1, comprising applying a vertical III-V device to the ceramic wafer.

11. A device comprising:
a ceramic wafer having a frontside to have integrated circuits built thereon and a backside, wherein the ceramic wafer comprises a SiC powder heated and pressed into an amorphous poly-SiC ceramic; and
a power line in the ceramic wafer, the power line comprising a conductive material comprising tungsten.

12. The device as in claim 11, wherein a thickness of the ceramic wafer is between 100-600 μm.

13. The device as in claim 11, comprising a power rail in the ceramic wafer, the power rail comprising a conductive material comprising tungsten, wherein the power rail is in electrical communication with the power line.

14. The device as in claim 11, comprising a spin on glass layer on the frontside of the ceramic wafer.

15. The device as in claim 14, wherein the spin on glass layer comprises particles having a relatively higher heat transfer coefficient than a material of the spin on glass layer.

16. The device as in claim 15, wherein a thickness of the spin on glass layer is between 2 and 20 μm, and the particles have a diameter dimension between .1 and 10 μm.

17. A system comprising:
a ceramic wafer having a frontside and a backside, wherein the ceramic wafer comprises a SiC powder heated and pressed into an amorphous poly-SiC ceramic;
a power line comprising a conductive material comprising tungsten in the ceramic wafer;
a power rail comprising a conductive material comprising tungsten in the ceramic wafer, wherein the power rail is in electrical communication with the power line; and
a semiconductor package applied to the ceramic wafer.

18. The system as in claim 17, wherein the semiconductor package comprises silicon photonics.

19. The system as in claim 17, wherein the semiconductor package comprises a CMOS device.

20. The system as in claim 17, wherein the semiconductor package comprises a vertical III-V device.
